(19) United States
(12) Patent Application Publication
(10) Pub. No.: US 2016/0260650 A1
(43) Pub. Date: Sep. 8, 2016

(54) SEMICONDUCTOR MODULE

(71) Applicant: TOYOTA JIDOSHA KABUSHIKI KAISHA, Toyota-shi (JP)

(72) Inventor: Etsushi TAGUCHI, Seto-shi (JP)

(73) Assignee: TOYOTA JIDOSHA KABUSHIKI KAISHA, Toyota-shi (JP)

(21) Appl. No.: 15/060,855

(22) Filed: Mar. 4, 2016

(30) Foreign Application Priority Data
Mar. 5, 2015 (JP) 2015-043956

(51) Int. Cl. H01L 23/367; B60L 11/18; H01L 27/06; H02P 27/06; H01L 29/739; H01L 29/861

(52) U.S. Cl. CPC H01L 23/367; H01L 29/7397; H01L 29/861; H01L 27/0629; H02P 27/06; B60L 11/1803

(57) ABSTRACT

A semiconductor module, which is mounted on an object for mounting and cooled by a cooler to which cooling medium is supplied, the semiconductor module includes: a package; a plurality of semiconductor elements arranged inside the package; and a temperature sensor provided in a part of the plurality of semiconductor elements. The semiconductor element having the temperature sensor is configured so as to be more adjacent to one edge part of the package than the other semiconductor element. The semiconductor module having the temperature sensor is mounted on the object for mounting such that the semiconductor element having the temperature sensor is located at an uppermost position among the plurality of semiconductor elements.

### INCORPORATION BY REFERENCE

The disclosure of Japanese Patent Application No. 2015-043956 filed on Mar. 5, 2015 including the specification, drawings and abstract is incorporated herein by reference in its entirety.

### BACKGROUND OF THE INVENTION

1. Field of the Invention

The invention relates to a semiconductor module that includes a plurality of semiconductor elements, is mounted on an object for mounting, and is cooled by a cooler to which cooling medium is supplied.

2. Description of Related Art

Conventionally, as this type of semiconductor module, a semiconductor module for a half bridge circuit is known, which includes a transistor chip and a diode chip, which structure upper arm side semiconductor chips, and a transistor chip and a diode chip, which structure lower arm element side semiconductor chips (for example, Japanese Patent Application Publication No. 2004-208411 (JP 2004-208411 A)). In this semiconductor module, the two transistor chips and the two diode chips are arrayed in a line in a direction of a long side of a middle side plate. The transistor chip and the diode chip, which structure the upper arm side semiconductor chips, are adjacent to each other along the direction of the long side of the middle side plate, and the transistor chip and the diode chip, which structure the lower arm element side semiconductor chips, are adjacent to each other along the direction of the long side.

Generally, the foregoing semiconductor module is cooled by supplying cooling medium into a cooler that is arranged so as to be in contact with the module. However, in the semiconductor module, when an amount of cooling medium supplied to the cooler is reduced for some reasons, and a liquid level inside the cooler is lowered, temperature of all of the semiconductor elements included in the semiconductor module increases due to deterioration of cooling performance. Therefore, even if a temperature sensor is provided in some of the plurality of semiconductor elements, timing of detecting deterioration of cooling performance of the cooler is delayed, which could cause overheating of the plurality of semiconductor elements.

### SUMMARY OF THE INVENTION

Therefore, the invention provides a semiconductor module to enable overheating of a plurality of semiconductor elements included in the semiconductor module to be restrained even when cooling performance of a cooler that cools the semiconductor module is deteriorated.

An aspect of the invention relates to a semiconductor module. The semiconductor module is mounted on an object for mounting and cooled by a cooler to which cooling medium is supplied. The semiconductor module includes a package, a plurality of semiconductor elements arranged inside the package, and a temperature sensor provided in a part of the plurality of semiconductor elements. The semiconductor element having the temperature sensor is structured so as to be more adjacent to one edge part of the package than the other semiconductor element, and the semiconductor module is mounted on the object for mounting so that the semiconductor element having the temperature sensor is located at an uppermost position among the plurality of semiconductor elements.

The semiconductor module includes the package and the plurality of semiconductor elements arranged inside the package, and a part of the plurality of semiconductor elements has the temperature sensor. Further, the semiconductor element having the temperature sensor is more adjacent to one edge part of the package than the other semiconductor elements. Then, the semiconductor module is mounted on the object for mounting so that the semiconductor element having the temperature sensor is located at the uppermost position among the plurality of semiconductor elements, and the semiconductor module is cooled by the cooler to which the cooling medium is supplied. Thus, when an amount of the cooling medium supplied to the cooler is reduced and a liquid level inside the cooler is lowered, temperature of the semiconductor element at the uppermost position among the plurality of the semiconductor elements, namely, the semiconductor element having the temperature sensor, increases earliest with deterioration of cooling performance of the cooler. Therefore, by monitoring a detection value of the temperature sensor provided in the semiconductor element located at the uppermost position, it is possible to swiftly detect deterioration of cooling performance of the cooler and swiftly carry out processing for protecting the plurality of semiconductor elements. As a result, even if cooling performance of the cooler, which cools the semiconductor module, is deteriorated, it is possible to restrain overheating of the plurality of semiconductor elements included in the semiconductor module.

The plurality of semiconductor elements may include an insulated gate bipolar transistor (IGBT) having the temperature sensor and a diode without the temperature sensor. Thus, by turning off the IGBT when the detection value of the temperature sensor of the IGBT exceeds a threshold, it is possible to favorably restrain overheating of both the IGBT and the diode even when cooling performance of the cooler is deteriorated.

Further, the semiconductor module may structure an inverter that drives an electric motor, and may be mounted on a vehicle having the electric motor driven by the inverter. Thus, by structuring the semiconductor module of the inverter that drives the electric motor of the vehicle as stated above, it is possible to restrain overheating of the inverter and improve durability of the inverter.

Moreover, the foregoing vehicle may have a plurality of the coolers arranged so as to be in contact with both surfaces of the semiconductor module, a reservoir tank that stores cooling medium, a pump that sucks in the cooling medium from the reservoir tank and feeds the cooling medium to the cooler under pressure, and a radiator that cools the cooling medium returned to the reservoir tank from the cooler.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a schematic configuration of an electric vehicle on which a power control unit including a semiconductor module according to the invention is mounted;

FIG. 2 is a schematic configuration of the semiconductor module according to the invention;

FIG. 3 is a schematic configuration of a cooling system mounted on the electric vehicle shown in FIG. 1;

FIG. 4 is a schematic configuration of coolers that structure the cooling system, and the semiconductor module, which are mounted on the electric vehicle shown in FIG. 1; and

FIG. 5 is a partial sectional view of the cooler that structures the cooling system, and the semiconductor module, which are mounted on the electric vehicle shown in FIG. 1.

### DETAILED DESCRIPTION OF EMBODIMENTS

Next, a mode for carrying out the invention is explained with reference to the drawings.

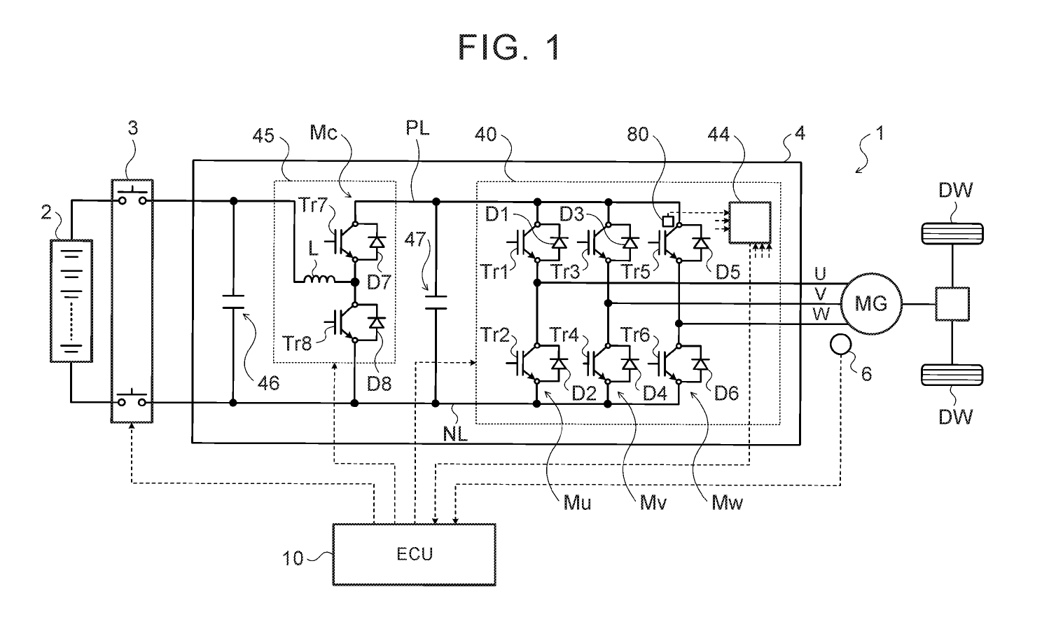

FIG. 1 is a schematic configuration of an electric vehicle 1 on which a power control unit including a semiconductor module according to the invention is mounted. The electric vehicle 1 shown in the drawing includes a motor MG connected with left and right driving wheels DW through a differential gear and so on, a battery 2, a power control unit (herein after, referred to as a “PCU”) 4 that is connected with the battery 2 through a system main relay 3 and drives the motor MG, and an electronic control unit (herein after, referred to as an “ECU”) 10 that controls the entire electric vehicle 1.

The motor MG is configured as a three-phase synchronous motor, and exchanges electric power with the battery 2 through the PCU 4. The motor MG is driven by electric power from the battery 2 and outputs traveling torque to the driving wheels DW. Further, the motor MG outputs regenerative braking torque to the driving wheels DW in braking the electric vehicle 1. Also, a rotation angle sensor (resolver) 6, which detects a rotation angle θ (rotational position) of a rotor, is provided in the motor MG. The battery 2 is a lithium-ion secondary battery or a nickel-hydrogen secondary battery. As illustrated, the system main relay 3 has a positive electrode side relay connected with a power line PL on a positive electrode side, and a negative electrode side relay connected with a power line NL on a negative electrode side.

The PCU 4 includes an inverter 40 that drives the motor MG, a boost converter (voltage conversion unit) 45 that boosts voltage of electric power from the battery 2, and smoothing capacitors 46 and 47. The inverter 40 includes six transistors (switching elements) Tr1, Tr2, Tr3, Tr4, Tr5, and Tr6, which are, for example, insulated gate bipolar transistors (IGBT), and six diodes D1, D2, D3, D4, D5, and D6 reversely connected in parallel to the transistors Tr1 to Tr6, respectively. The six transistors Tr1 to Tr6 form pairs so that one in each pair is on a source side and the other is on a sink side with respect to the power line PL on the positive electrode side and the power line NL on the negative electrode side. Further, with each of connecting points between the two transistors that form a pair, any one of corresponding phases of a three-phase coil (U phase, V phase, and W phase) of the motor MG is electrically connected.

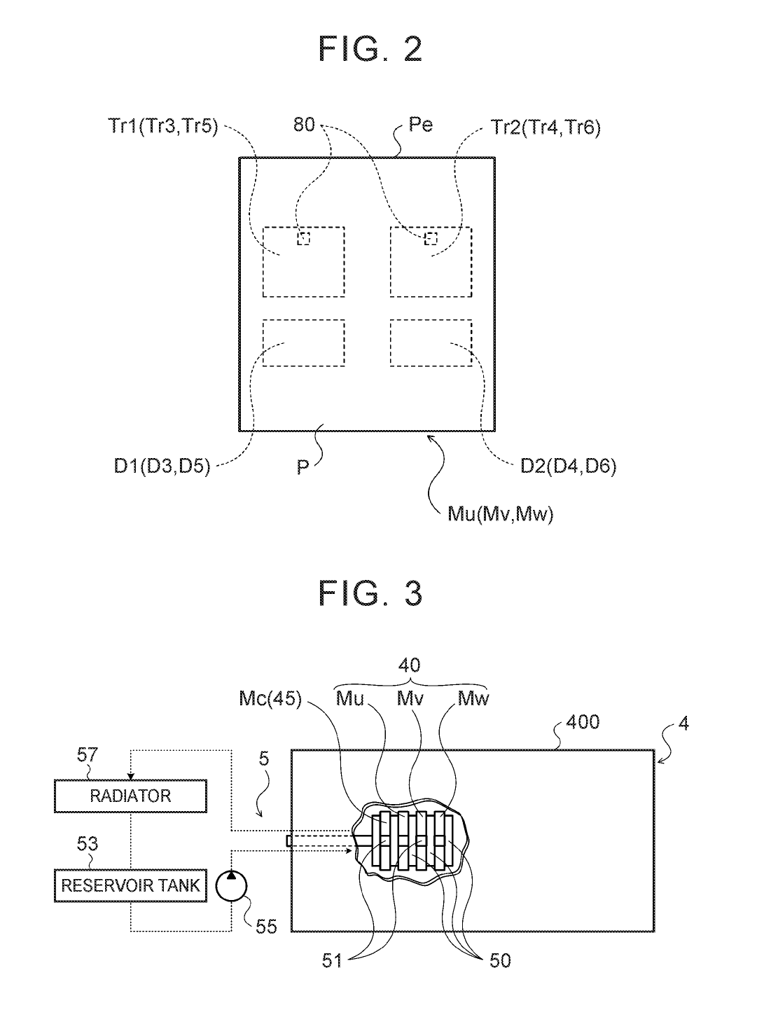

In this embodiment, as shown in FIG. 2, the transistors Tr1, Tr2 and the diodes D1 and D2 corresponding to the U phase of the motor MG are arranged (buried) in a package P made by resin molding, thereby configuring a single semiconductor module Mu together with the package P. The transistors Tr3, Tr4 and the diodes D3, D4 corresponding to the V phase of the motor MG are arranged (buried) in a package P made by resin molding, thereby configuring a single semiconductor module Mv together with the package P. Further, the transistors Tr5, Tr6 and the diodes D5, D6 corresponding to the W phase of the motor MG are arranged (buried) in a package P made by resin molding, thereby configuring a single semiconductor module Mw together with the package P. In this embodiment, the package P of each of the semiconductor modules Mu, Mv, Mw is formed into a rectangular plate shape as shown in FIG. 2, and a heat sink (not shown) is provided on front and back surfaces (two surfaces other than narrow side surfaces) of the case of the package. The transistors Tr1 to Tr6 are provided with temperature sensors 80 that detect temperature of the transistors Tr1 to Tr6, respectively (in FIG. 1, only the temperature sensor 80 for the transistor Tr5 is shown).

Further, the inverter 40 includes a self-protective circuit 44 for protecting the transistors Tr1 to Tr6 and the diodes D1 to D6, and the temperature sensors 80 of the transistors Tr1 to Tr6 are connected with the self-protective circuit 44. The self-protective circuit 44 compares temperature detected by the temperature sensors 80 of the transistors Tr1 to Tr6 to predetermined threshold temperature, and outputs an abnormality detection signal when a detection value of the temperature sensor 80 provided in any one of the transistors Tr1 to Tr6 exceeds the threshold temperature. In this embodiment, the self-protective circuit 44 also outputs the abnormality detection signal when current (phase current) flowing in each of the phases of the motor MG, detected by a current sensor (not shown), exceeds predetermined threshold current.

The boost converter 45 includes two transistors Tr7, Tr8, which are, for example, insulated gate bipolar transistors (IGBT), two diodes D7, D8 that are reversely connected in parallel with the transistors Tr7, Tr8, respectively, and a reactor L. One end of the reactor L is electrically connected with a positive electrode terminal of the battery 2 through the system main relay 3, and, an emitter of one of the transistors Tr7 (upper arm) and a collector of the other transistor Tr8 (lower arm) are electrically connected with the other end of the reactor L. A collector of the transistor Tr7 is electrically connected with the power line PL on the positive electrode side, and an emitter of the transistor Tr8 is electrically connected with the power line NL on the negative electrode side. In this embodiment, the transistors Tr7, Tr8 and the diodes D7, D8 of the boost converter 45 are also arranged (buried) in a package made by resin molding, thereby configuring a single semiconductor module Mc together with the package.

The smoothing capacitor 46 is arranged between the system main relay 3 and the boost converter 45, and performs smoothing of voltage on the battery 2 side of the boost converter 45, namely, voltage before boosting VL. Further, the smoothing capacitor 47 is arranged between the boost converter 45 and the inverter 40, and performs smoothing of voltage after boosting VH, which is boosted by the boost converter 45.

The ECU 10 is configured as a microcomputer including a CPU (not shown), and inputs a system startup command and a system stop command from a start switch (ignition switch) (not shown), a rotation angle θ of the motor MG, which is detected by the rotation angle sensor 6, voltage before boosting VL and voltage after boosting VH detected by a voltage sensor (not shown), a value of phase current from the current sensor (not shown), an abnormality detection signal from the self-protective circuit 44, and so on. The ECU 10 generates a switching control signal for each of the transistors of the inverter 40 and the boost converter 45 based on these input signals, and performs switching control of the inverter 40 and the boost converter 45.

Further, upon receipt of the abnormality detection signal from the self-protective circuit 44 of the inverter 40, the ECU 10 stops the foregoing switching control and turns off the transistors Tr1 to Tr8, so as to shut down the inverter 40 and the boost converter 45. Thus, it is possible to restrain overheating of the transistors Tr1 to Tr8 and the diodes D1 to D8 and flowing of excess current in the transistors Tr1 to Tr8 and the diodes D1 to D8. Further, the ECU 10 carries out control for opening and closing the system main relay 3. The above-mentioned functions of the ECU 10 may be distributed into a plurality of electronic control units.

FIG. 3 is a schematic configuration of a cooling system 5 for cooling the PCU 4, namely, the inverter 40, the boost converter 45 and so on. As shown in the drawing, the cooling system 5 includes a plurality of coolers 50, a reservoir tank 53 that stores cooling medium (cooling liquid) such as LLC (long life coolant), a refrigerant pump 55, and a radiator 57.

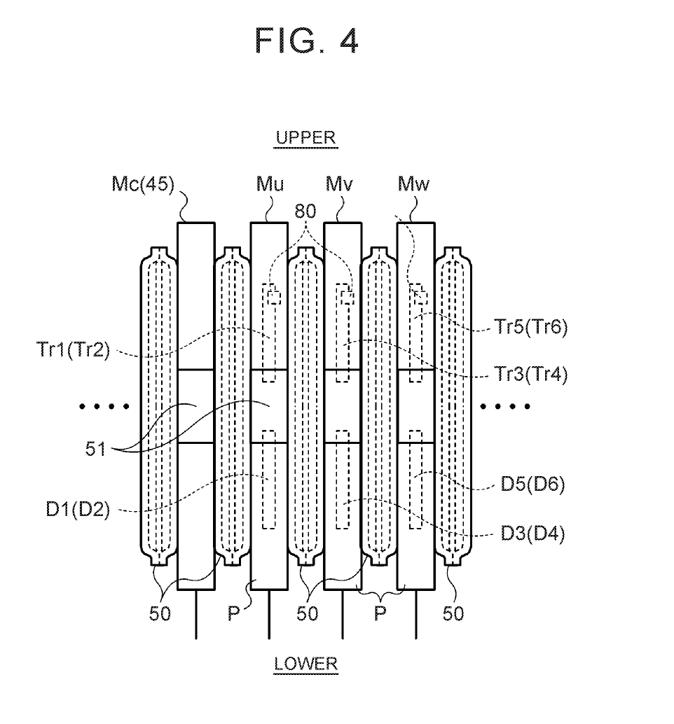

As shown in FIG. 3 and FIG. 4, the plurality of coolers 50 are arranged so as to be aligned alternately with the plurality of semiconductor modules Mu, Mv, Mw, which configure the inverter 40, and the semiconductor module Mc, which configures the boost converter 45. In other words, two coolers 50 are arranged for one of the semiconductor modules so that the coolers 50 are in contact with a front surface and a back surface of the module, respectively. Further, the coolers 50 neighboring to each other are communicated with each other inside through a communicating pipe 51. The refrigerant pump 55 sucks in the cooling medium from the reservoir tank 53 and feeds the cooling medium under pressure to the cooler 50 that is located on one end side and closest to the refrigerant pump 55. The cooling medium supplied to the cooler 50 is successively flown into the coolers 50 neighboring to each other, and the cooling medium flowing inside each of the coolers 50 takes heat from the semiconductor module Mu and so on that are in contact with the coolers 50, and temperature of the cooling medium increases. The cooling medium flowing out from each of the coolers 50 flows into a heat exchange part of the radiator 57, is cooled by the radiator 57 and then returned to the reservoir tank 53. Thus, it becomes possible that each of the coolers 50 cools the semiconductor modules Mu, Mv, Mw, Mc by supplying and circulating the cooling medium inside the plurality of coolers 50.

Here, while the electric vehicle 1 is traveling, a leakage of the cooling medium could happen due to, for example, a flying gravel and so on hitting the radiator 57.

When such a leakage of the cooling medium happens, a liquid level of the reservoir tank 53 is lowered, thereby causing the refrigerant pump 55 to suck in air or making the refrigerant pump 55 unable to feed the cooling medium under pressure. Further, when an amount of the cooling medium supplied to each of the coolers 50 from the refrigerant pump 55 is reduced, a liquid level inside each of the coolers 50 is lowered, and cooling performance is deteriorated. Thus, temperature of the semiconductor modules Mu, Mv Mw, which configure the inverter 40, as well as temperature of the transistors Tr1 to Tr8 and the diodes D1 to D8 included in the semiconductor module Mc, which configures the boost converter 45, are increased.

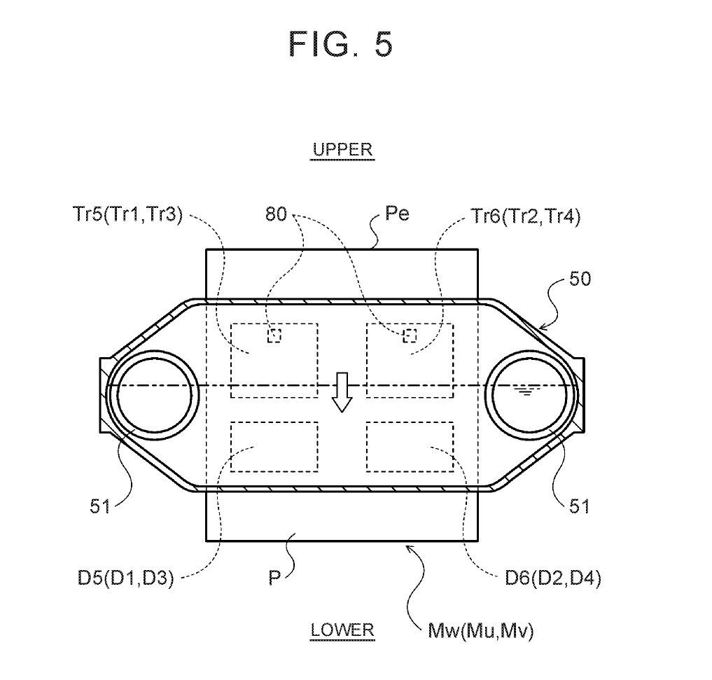

Based on this, as shown in FIG. 2 and FIG. 5, the semiconductor module Mu of the inverter 40 is manufactured (configured) so that the transistors Tr1 and Tr2, which are semiconductor elements having the temperature sensors 80, are more adjacent to any one of edge parts (one edge part) Pe (see FIG. 2 and FIG. 4, an upper edge part in the drawings) of the resin-made package P compared to the diodes D1 and D2 having no temperature sensors 80, and are arrayed in a line along the edge part Pe. Similarly, the semiconductor module Mv of the inverter 40 is manufactured (configured) so that the transistors Tr3 and Tr4 having the temperature sensors 80 are more adjacent to any one of edge parts Pe of the package P compared to the diodes D3 and D4, and are arrayed in a line along the edge part Pe. The semiconductor module Mw of the inverter 40 is manufactured (configured) so that the transistors Tr5 and Tr6 having the temperature sensors 80 are more adjacent to any one of edge parts Pe of the package P compared to the diodes D5 and D6, and are arrayed in a line along the edge part Pe.

Further, the semiconductor modules Mu, Mv, Mw are arranged inside a case 400 (see FIG. 3) of the PCU 4 so that the semiconductor modules Mu, Mv, Mw are arrayed alternately with the coolers 50, and the edge parts Pe of the packages P, namely, the transistors Tr1 to Tr6 are positioned on a top plate side of the case 400. Then, the PCU 4 is mounted on the electric vehicle 1 so that the edge parts Pe of the packages P of the semiconductor modules Mu, Mv, Mw, namely, the transistors Tr1 to Tr6 are positioned on a vertically upper side. Thus, when the PCU 4 is mounted on the electric vehicle 1, the transistors Tr1 and Tr2 having the temperature sensors 80 are located at the uppermost position among all of the elements in the semiconductor module Mu, the transistors Tr3 and Tr4 having the temperature sensors 80 are located at the uppermost position among all of the elements in the semiconductor module Mv, and the transistors Tr5 and Tr6 having the temperature sensors 80 are located at the uppermost position among all of the elements in the semiconductor module Mw.

As a result, when an amount of cooling medium supplied to each of the coolers 50 from the refrigerant pump 55 is reduced while the electric vehicle 1 is traveling and so on, and a liquid level (see the alternate long and two short dashed line in FIG. 5) inside at least any one of the coolers 50 (for example, the cooler 50 that is the farthest from the refrigerant pump 55) is lowered, temperature of at least any one of transistors Tr1 to Tr6, which is located at the uppermost position in any one of the semiconductor modules Mu, Mv, Mw that are in contact with the coolers 50, increases earliest with deterioration of cooling performance of the coolers 50. Therefore, by monitoring detection values of the temperature sensors 80 provided in the transistors Tr1 to Tr6, it becomes possible to swiftly detect deterioration of cooling performance of the coolers 50, and to swiftly carry out processing for protecting the transistors Tr1 to Tr6 and the diodes D1 to D6 of the semiconductor modules Mu, Mv, Mw (the inverter 40) and also the transistors Tr7, Tr8 and the diodes D7, D8 of the semiconductor module Mc (the boost converter 45).

Thus, in the electric vehicle 1, when a detection value from the temperature sensor 80 provided in any one of the transistors Tr1 to Tr6 exceeds the foregoing threshold temperature, the self-protective circuit 44 of the inverter 40 outputs an abnormality detection signal, and the ECU 10, which has received the abnormality detection signal, turns the transistors Tr1 to Tr8 off, thereby shutting down the inverter 40 and the boost converter 45. Because of this, even if cooling performance of any one of the coolers 50 is deteriorated, it is possible to favorably restrain overheating of the transistors Tr1 to Tr8 and the diodes D1 to D8 included in the semiconductor modules Mu, Mv, Mw, Mc. Therefore, in the electric vehicle 1, overheating of the inverter 40 and the boost converter 45 is restrained, thereby making it possible to improve durability of the inverter 40 and the boost converter 45 more.

As explained so far, the semiconductor module Mu, Mv, and Mw, which configure the inverter 40 of the PCU 4 include the packages P, the transistors Tr1, Tr2 and the diodes D1 and D2, the transistors Tr3, Tr4 and the diodes D3, D4, and the transistors Tr5, Tr6 and the diode D5, D6, which are arranged inside the packages P, respectively. The transistors Tr1 to Tr6 have the temperature sensors 80, respectively. Further, the transistors Tr1, Tr2 are more adjacent to the edge part Pe of the package P than the diodes D1 and D2, the transistors Tr3, Tr4 are more adjacent to the edge part Pe of the package P than the diodes D3, D4, and the transistors Tr5, Tr6 are more adjacent to the edge part Pe of the package P than the diodes D5, D6. Then, the semiconductor module Mu, Mv, and Mw are mounted on the electric vehicle 1 so that the transistors Tr1, Tr2, the transistors Tr3, Tr4, and the transistors Tr5, Tr6 are located at the uppermost positions among all of the semiconductor elements included in each of the semiconductor module Mu, Mv, and Mw, and are cooled by the coolers 50 to which the cooling medium is supplied. Thus, by monitoring detection values of the temperature sensors 80 provided in the transistors Tr1 to Tr6, it is possible to swiftly detect deterioration of cooling performance of the cooler 50 and to swiftly carry out processing for protecting the transistors Tr1 to Tr6 and the diodes D1 to D6. Therefore, even if cooling performance of the cooler 50 is deteriorated, it is possible to favorably restrain overheating of the transistors Tr1 to Tr6 and the diodes D1 to D6 included in the semiconductor module Mu, Mv, and Mw.

It is not always necessary to provide the temperature sensors 80 in all of the transistors Tr1 to Tr6, which configure the inverter 40. This means that the temperature sensor 80 may be provided in at least one of the transistors that could be located at the vertically uppermost position among all of the elements, in consideration of a mounted state of the PCU 4 on the electric vehicle 1 (for example, a case where the PCU 4 is mounted while being slightly inclined with respect to a vehicle body) and an attitude of the PCU 4 while the electric vehicle 1 is traveling (including traveling uphill and downhill). Further, the self-protective circuit may be built in at least any one of the transistors Tr1 to Tr6 of the inverter 40. Further, the semiconductor module Mc, which configures the foregoing boost converter 45, may be configured similarly to the semiconductor modules Mu, Mv, and Mw of the inverter 40, and a self-protective circuit similar to the foregoing self-protective circuit 44 may be provided in the boost converter 45 or the transistors Tr7, Tr8. Moreover, needless to say, the structure of the foregoing electric vehicle 1 is applicable to a hybrid vehicle (that may or may not include a planetary gear for power distribution) that includes two or more motors (invertors), and a so-called single motor type hybrid vehicle, a series hybrid vehicle, and so on.

The invention is not limited to the foregoing embodiment, and it is needless to say that various changes may be made within the scope of the breadth of the invention. Further, the mode for carrying out the invention described above is just one of specific modes of the invention described in “SUMMARY OF THE INVENTION”, and does not limit elements of the invention described in “SUMMARY OF THE INVENTION”.

The invention is usable in a field of manufacturing a power control unit including a semiconductor module and an inverter provided with the semiconductor module, and so on.

What is claimed is:

1. A semiconductor module, which is mounted on an object for mounting and cooled by a cooler to which cooling medium is supplied, the semiconductor module comprising:
a package;
a plurality of semiconductor elements arranged inside the package; and
a temperature sensor provided in a part of the plurality of semiconductor elements, wherein
the semiconductor element having the temperature sensor is configured so as to be more adjacent to one edge part of the package than the other semiconductor element, and
the semiconductor module having the temperature sensor is mounted on the object for mounting such that the semiconductor element having the temperature sensor is located at an uppermost position among the plurality of semiconductor elements.

2. The semiconductor module according to claim 1, wherein
the plurality of semiconductor elements include an insulated gate bipolar transistor having the temperature sensor, and a diode without the temperature sensor.

3. The semiconductor module according to claim 1, wherein
the object for mounting is a vehicle that includes an inverter for driving an electric motor, and has the electric motor driven by the inverter.

4. The semiconductor module according to claim 3, wherein
the vehicle has a plurality of the coolers arranged so as to be in contact with both surfaces of the semiconductor module, a reservoir tank that stores cooling medium, a pump that sucks in the cooling medium from the reservoir tank and feeds the cooling medium to the cooler under pressure, and a radiator that cools the cooling medium returned to the reservoir tank from the cooler.
